(19) United States
(12) Patent Application Publication
(10) Pub. No.: US 2017/0077111 A1
(43) Pub. Date: Mar. 16, 2017

(54) NONVOLATILE SEMICONDUCTOR MEMORY DEVICE AND METHOD OF MANUFACTURING THE SAME

(71) Applicant: KABUSHIKI KAISHA TOSHIBA, Minato-ku (JP)

(72) Inventor: Ryuji OHBA, Yokkaichi (JP)

(73) Assignee: KABUSHIKI KAISHA TOSHIBA, Minato-ku (JP)

(21) Appl. No.: 15/044,373

(22) Filed: Feb. 16, 2016

Related U.S. Application Data
(60) Provisional application No. 62/217,424, filed on Sep. 11, 2015.

(51) Int. Cl. H01L 27/115; H01L 21/28; H01L 29/423; H01L 29/788; H01L 29/66

(52) U.S. Cl. CPC H01L 27/11524; H01L 29/788; H01L 29/66825; H01L 29/42324; H01L 21/28273

(57) ABSTRACT

A semiconductor memory device according to an embodiment includes a plurality of channel layers, a gate-insulating film disposed on the channel layer, a floating gate electrode disposed on the gate-insulating film, a block insulating film disposed over the floating gate electrode, the block insulating film including at least a first insulating film and a second insulating film, the second insulating film including lanthanum and aluminum, and a control gate electrode disposed on the block insulating film. The second insulating film includes an upwardly convex curved portion in a region between the channel layers.

### CROSS REFERENCE TO RELATED APPLICATION

This application is based upon and claims the benefit of priority from U.S. Provisional Patent Application No. 62/217,424, filed on Sep. 11, 2015, the entire contents of which are incorporated herein by reference.

### FIELD

The embodiments described herein relate to a non-volatile semiconductor memory device and a method of manufacturing the same.

### BACKGROUND

Description of the Related Art

Memory cells form a part of a non-volatile semiconductor memory device such as a NAND flash memory. Each memory cell changes its threshold voltage according to charge accumulated in a floating gate electrode and a charge accumulation film, and stores the value of the threshold voltage as data. Recently, the non-volatile semiconductor memory device is requested to become more compact. It is needed to achieve the more compactness as well as ensure capacitance in the memory cells and reduce the interference between the adjacent memory cells.

### BRIEF DESCRIPTION OF THE DRAWINGS

FIG. 1 is a block diagram of a non-volatile semiconductor memory device according to a first embodiment;

FIG. 2 is a circuit diagram partially illustrating the configuration of the non-volatile semiconductor memory device according to the first embodiment.

FIG. 3 is a planar layout diagram partially illustrating the configuration of the non-volatile semiconductor memory device according to the first embodiment;

FIG. 4 is a cross-sectional view partially illustrating the configuration of the non-volatile semiconductor memory device according to the first embodiment;

FIG. 5 is a cross-sectional view partially illustrating the configuration of the non-volatile semiconductor memory device according to the first embodiment;

FIGS. 6 to 11 are cross-sectional views illustrating a manufacturing process of the non-volatile semiconductor memory device according to the first embodiment;

FIG. 12 is a cross-sectional view partially illustrating the configuration of a non-volatile semiconductor memory device according to a second embodiment;

FIG. 13 is a cross-sectional view partially illustrating the configuration of a non-volatile semiconductor memory device according to a third embodiment;

FIG. 14 is a cross-sectional view partially illustrating the configuration of a non-volatile semiconductor memory device according to a fourth embodiment.

FIG. 15 is across-sectional view partially illustrating the configuration of a non-volatile semiconductor memory device according to a fifth embodiment.

FIGS. 16 to 17 are cross-sectional views partially illustrating a manufacturing process of the non-volatile semiconductor memory device according to the fifth embodiment;

FIG. 18 is across-sectional view partially illustrating the configuration of a non-volatile semiconductor memory device according to a sixth embodiment;

FIGS. 19 to 25 are cross-sectional views illustrating a manufacturing process of the non-volatile semiconductor memory device according to the sixth embodiment;

FIG. 26 is across-sectional view partially illustrating the configuration of a non-volatile semiconductor memory device according to a seventh embodiment.

FIGS. 27 to 29 are cross-sectional views partially illustrating a manufacturing process of the non-volatile semiconductor memory device according to the seventh embodiment;

FIG. 30 is across-sectional view partially illustrating the configuration of a non-volatile semiconductor memory device according to an eighth embodiment;

FIG. 31 is a cross-sectional view partially illustrating the configuration of a non-volatile semiconductor memory device according to a ninth embodiment; and

FIG. 32 is across-sectional view partially illustrating the configuration of the non-volatile semiconductor memory device according to the comparative example.

### DETAILED DESCRIPTION

The non-volatile semiconductor memory device described below includes a plurality of channel layers, a gate-insulating film disposed on the channel layers, a floating gate electrode disposed on the gate-insulating film, a block insulating film disposed over the floating gate electrode, the block insulating film including at least a first insulating film and a second insulating film, the second insulating film including lanthanum and aluminum, and a control gate electrode disposed on the block insulating film. The second insulating film has an upwardly convex curved portion in the region between the channel layers.

Referring now to the drawings, the non-volatile semiconductor memory devices according to embodiments and embodiments of the manufacturing method will be described.

### First Embodiment

### Entire Configuration

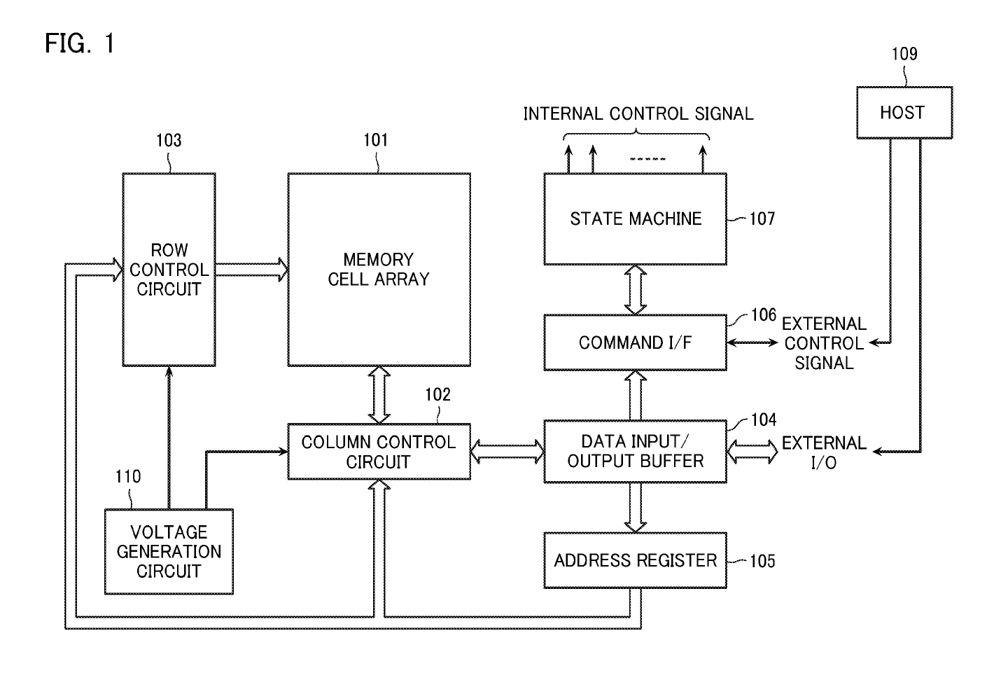

FIG. 1 is a block diagram of a non-volatile semiconductor memory device according to a first embodiment. The non-volatile semiconductor memory device includes a memory cell array 101. The memory cell array 101 includes memory cells MC disposed in a generally matrix as well as bit-lines BL and word-lines WL connected to the memory cells MC. The bit-lines BL and the word-lines WL are perpendicular to each other. The memory cell array 101 has, around it, a column control circuit 102 and a row control circuit 103. The column control circuit 102 controls the bit-lines BL, erases data in the memory cells, writes data in the memory cells, and reads data from the memory cells. The row control circuit 103 selects a word-line WL, and applies a voltage for erasing data in the memory cells, writing data in the memory cells, and reading data from the memory cells.

A data input/output buffer 104 is connected to an external host 109 via an I/O line. The data input/output buffer 104 receives write data, receives erase command, outputs read data, and receives address data and command data from the external host 109. The data input/output buffer 104 sends the received write data to the column control circuit 102, receives data read from the column control circuit 102, and outputs it externally. The address externally provided to the data input/output buffer 104 is sent via an address register 105 to the column control circuit 102 and the row control circuit 103.

In addition, the command provided from the host 109 to the data input/output buffer 104 is sent to a command interface 106. The command interface 106 receives an external control signal from the host 109 and determines whether data input to the data input/output buffer 104 is write data, a command, or an address. If the data is a command, the command interface 106 transfers it to a state machine 107 as a received command signal.

The state machine 107 manages the entire non-volatile memory. The state machine 107 receives a command from the host 109 via the command interface 106 to manage data receiving, reading, writing, erasing, input/output or the like.

In addition, the external host 109 may receive status information managed by the state machine 107 to determine the operation result. The status information is also used to control the write and erase.

In addition, the state machine 107 controls a voltage generation circuit 110. This control may allow the voltage generation circuit 110 to output any voltage and any timing pulse.

Here, the formed pulse may be transferred to any wiring line selected by the column control circuit 102 and the row control circuit 103. The column control circuit 102, the row control circuit 103, the state machine 107, and the voltage generation circuit 110 or the like form the control circuit in this embodiment.

### [Memory Cell Array 101]

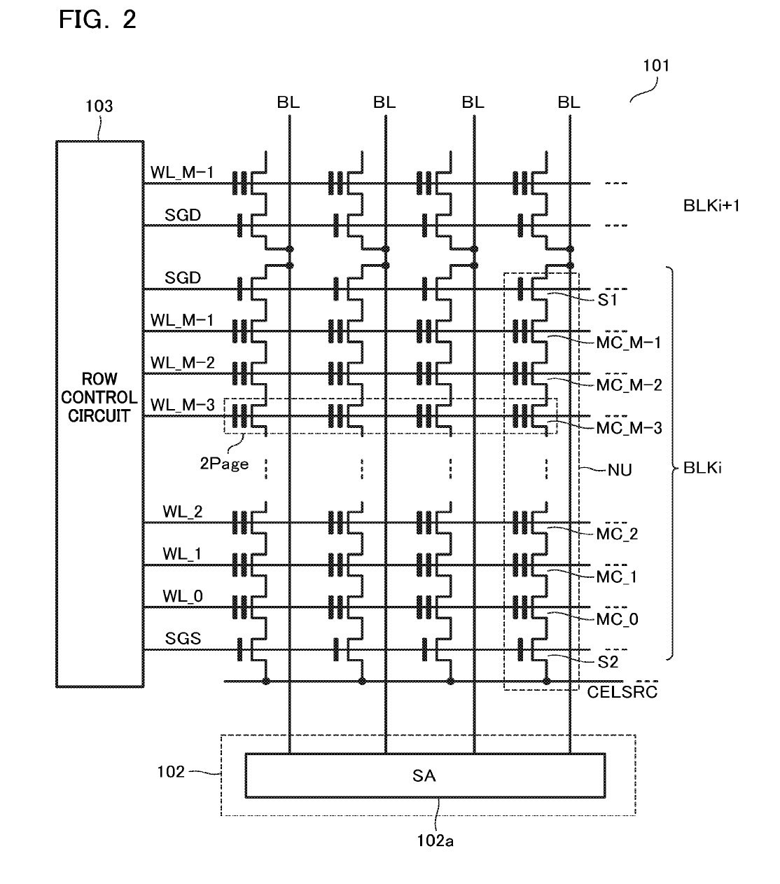

FIG. 2 is a circuit diagram showing the configuration of the memory cell array 101. As shown in FIG. 2, the memory cell array 1 includes an array of a plurality of NAND cell units NU. Each NAND cell unit NU includes a NAND string and select gate transistors S1 and S2 connected to the opposite ends of the NAND string. The NAND string includes electrically rewritable M non-volatile memory cells MC_0 to MC_M−1 connected in series. The non-volatile memory cells MC_0 to MC_M−1 share sources and drains.

Each NAND cell unit NU has a first end (on the select gate transistor S1 side) connected to a bit-line BL and a second end (on the select gate transistor S2 side) connected to a common source-line CELSRC. The select gate transistors S1 and S2 have gate electrodes connected to respective select-gate-lines SGD and SGS. In addition, the memory cells MC_0 to MC_M−1 have control gate electrodes connected to respective word-lines WL_0 to WL M−1. The bit-lines BL are connected to a sense amplifier 102a of the column control circuit 102. The word-lines WL_0 to WL M−1 and the select-gate-lines SGD and SGS are connected to the row control circuit 103.

For 2-bit/cell in which one memory cell MC stores 2-bit data, data stored in the memory cells MC connected to one word-line WL forms data of 2 pages (an upper page UPPER and a lower page LOWER).

A plurality of NAND cell units NU sharing the word-lines WL form one block BLK. One block BLK forms one unit for a data erase operation. In one memory cell array 1, one block BLK includes M word-lines WL and one block includes M×2 pages for 2-bit/cell.

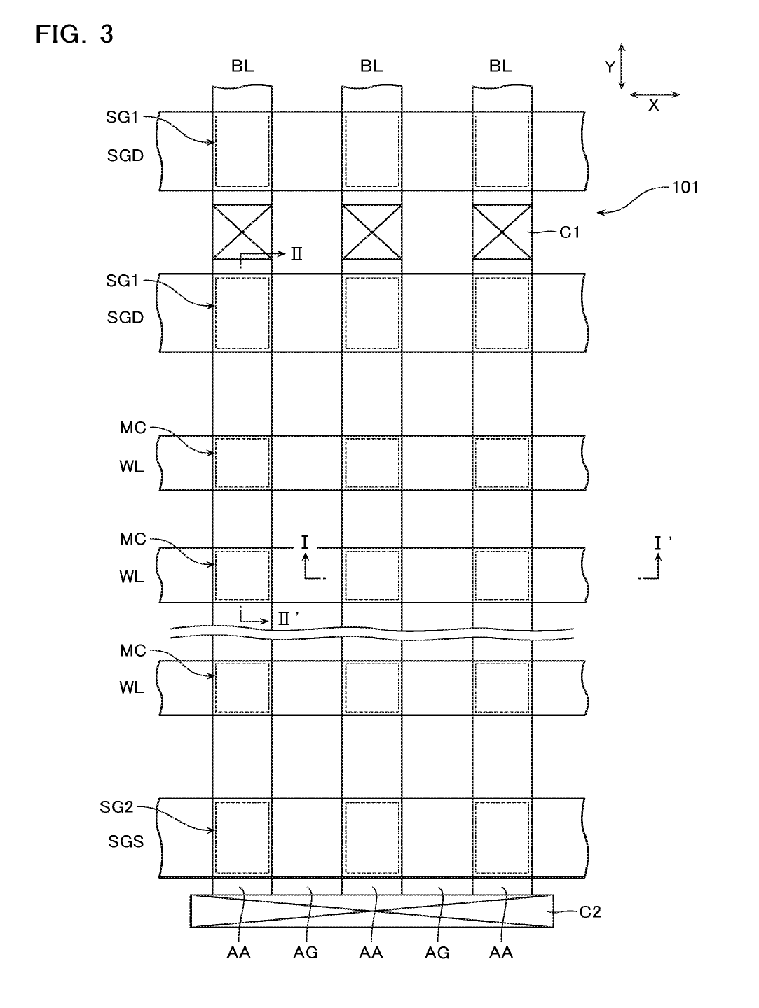

Next, the detailed configuration of the memory cell array 101 will be described with reference to FIG. 3.

FIG. 3 is a plan view showing the layout of the memory cell array 101. As shown in FIG. 3, the memory cell array 101 includes a plurality of word-lines WL and bit-lines BL intersecting each other. Each intersection has a memory cell MC formed therein. Here, the direction in which the word-lines extend is defined as a word-line direction (X direction) and the direction in which the bit-lines BL extend is defined as a bit-line direction (Y direction).

The memory cells MC arranged in the bit-line direction (Y direction) are connected in series and form one memory string. As described below, the memory cells MC are formed in a semiconductor substrate that includes air gaps AG formed in the Y direction as the longitudinal direction. The air gaps AG separate the semiconductor substrate into a plurality of active areas AA. Along the active areas AA, the memory strings are formed. Specifically, the active areas AA function as the channel layers in the non-volatile semiconductor memory device.

The memory strings arranged in the X direction are commonly connected to the same word-line WL and form one memory block. The memory block is the minimum unit of the data erase operation. Note that at least one of the memory cells MC included in each memory string may be a dummy cell not used in data storage.

Each memory string has a first end connected to a bit-line BL via the drain-side select gate transistor SG1. The bit-line BL and the drain-side select gate transistor SG1 are connected via a contact C1.

In addition, the memory string has a second end connected to a not-shown source-line SL via the source-side select gate transistor SG2. The source-line SL and the source-side select gate transistor SG2 are connected via a source-side contact C2.

The drain-side select gate transistor SG1 has a gate connected to the drain-side select gate line SGD provided in parallel with the word-lines WL. In addition, the source-side select gate transistor SG2 has a gate connected to the source-side select gate line SGS provided in parallel with the word-lines WL.

### [Configuration of Memory Cell MC]

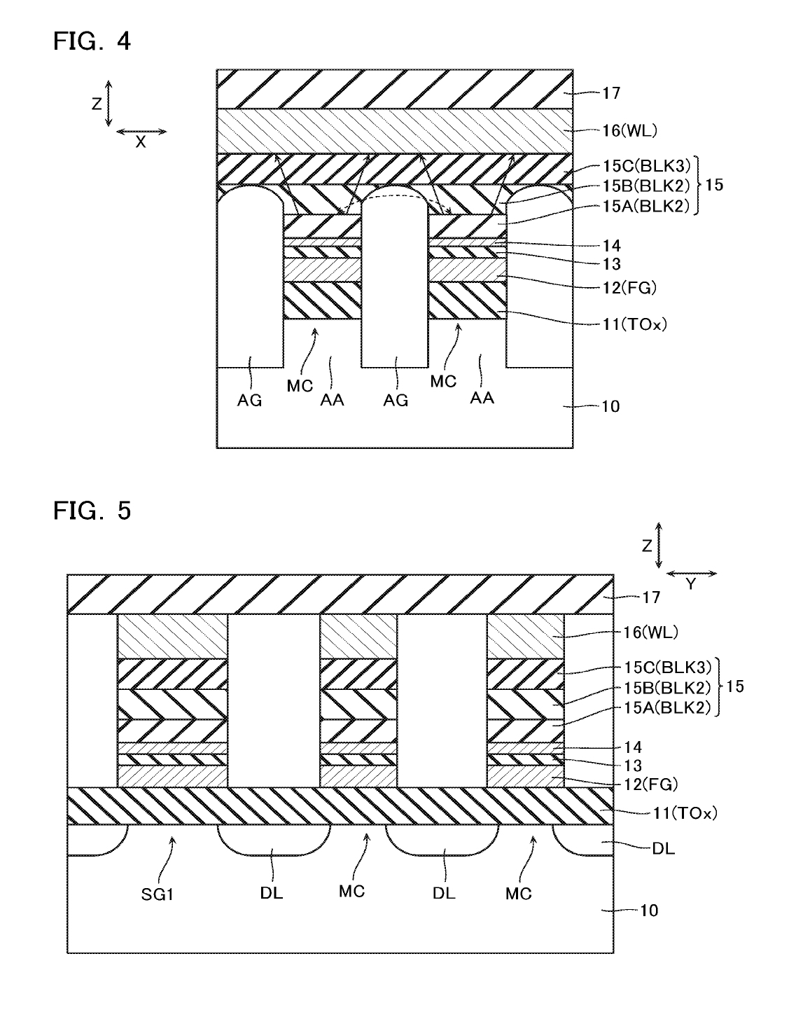

Next, the cross-sectional structure of the memory cell MC will be described with reference to FIG. 4 and FIG. 5. FIG. 4 and FIG. 5 are the I-II′ cross-sectional view and the II-II′ cross-sectional view in FIG. 3, respectively.

The memory cells MC are formed in the semiconductor substrate 10 as shown in FIG. 4 and FIG. 5. The semiconductor substrate 10 has a surface in which the air gaps AG extending in the Y direction as the longitudinal direction are formed in the X direction at a predetermined interval. The region of the semiconductor substrate 10 sandwiched between the adjacent air gaps AG provides an active area AA where the memory strings (the memory cells) are formed. Specifically, the surface of the semiconductor substrate 10 is electrically separated into a plurality of active areas AA by the air gaps AG. The active areas function as the channel layers of the memory strings as described above. The active areas AA may thus be referred hereinafter to as channel layers or channel regions.

The active areas AA extend, like the air gaps AG, in the Y direction as the longitudinal direction and are formed in the X direction at a predetermined interval. In addition, each air gap AG may have an X direction width of, for example, about 10 to 15 nm. In other words, the memory cells MC disposed in the X direction may be disposed at an interval of about 10 to 15 nm.

As shown in FIG. 5, the memory cells MC each include a plurality of source/drain diffusion layers DL disposed in the surface of the semiconductor substrate 10, a gate-insulating film 11 (a tunnel insulating film) disposed on at least the channel region between the source/drain diffusion layers DL, and a floating gate electrode 12 disposed on the gate-insulating film 11. The gate-insulating film 11 may have a film thickness of, for example, about 7 nm. Note that the select gate transistors SG1 and SG2 have a Y direction cross-sectional structure generally the same as that of each memory cell MC. The gate-insulating film 11 includes, for example, a thermally-oxidized film of silicon. The floating gate electrode 12 includes, for example, polysilicon.

In addition, the floating gate electrode 12 may have a film thickness of, for example, about 2 to 10 nm. Note that when the memory cells MC have a short distance between them, the source/drain diffusion layers DL may be omitted. This is because the so-called fringe effect may generate, without the source/drain diffusion layers DL, conductive paths passing through the channel regions of the memory cells MC.

Additionally, the memory cell MC includes an insulating film 13 disposed on the floating gate electrode 12. The insulating film 13 is made of, for example, silicon nitride (SiN). The insulating film 13 may have a film thickness of, for example, about 0.5 to 2 nm. The insulating film 13 has a surface having a metal layer 14 stacked thereon. The floating gate electrode 12, the insulating film 13, and the metal layer 14 form a stacked structure that functions as a charge accumulation layer. The insulating layer 13 may be made of, for example, silicon nitride and the metal layer 14 may be made of, for example, ruthenium (Ru). The metal layer 14 may include a small amount of metal. The metal layer 14 may be an ultrathin film of a thickness 0.1 to 1 nm, or include metal small particles dispersed therein. The charge accumulation layer may reduce the aspect ratio of the floating gate electrode 12.

Additionally, although this embodiment has been described with respect to a charge accumulation layer having a three layer structure as described above, the charge accumulation layer may have a single layer structure or a two layer structure. Then, various combinations are possible such as the floating gate electrode 12 or the metal layer 14 alone, a stacked structure of an electrically conductive layer or the metal layer and the insulating layer.

The metal layer 14 of the charge accumulation layer has a block insulating film 15 formed thereon. The block insulating film 15 includes, by way of example, a lower insulating film 15A of hafnium oxide (HfO₂), an intermediate insulating film 15B of lanthanum aluminum silicate (LaAlSiO), and an upper insulating film 15C of hafnium oxide (HfO₂).

The lower and upper insulating films 15A and 15C may each have a film thickness of, by way of example, about 4 to 5 nm. In addition, the intermediate insulating layer 15B may have a film thickness of, by way of example, about 2 nm Equivalent Oxide Thickness (EOT). Specifically, for example, the intermediate insulating layer 15B of lanthanum aluminum silicate (LaAlSiO) may have a physical film thickness of about 6 nm.

The lower and upper insulating layers 15A and 15C are a so-called high-permittivity insulating film (High-k film) that has a relative permittivity higher than the relative permittivity (of about 3.9) of silicon oxide. The lower and upper insulating layers 15A and 15C may include hafnium oxide (HfO₂) as well as aluminum oxide (Al₂O₃), titanium oxide (TiO₂), tantalum oxide (Ta₂O₅), hafnium silicate (HfSiO), nitrided hafnium silicate (HfSiON) with a small addition of silicon or the like.

Additionally, the intermediate insulating layer 15B is a high-permittivity insulating film like the lower and upper insulating layers 15C and 15A. In addition, the intermediate insulating layer 15B in this embodiment has, among the high-permittivity insulating films, a wide band gap and may include lanthanum aluminum silicate as well as aluminum oxide or the like. Note, however, that in any case, it is preferable to use a film including at least aluminum or aluminum and lanthanum. In addition, the intermediate insulating layer 15B may include hafnium (Hf) or zirconium (Zr).

The lower insulating film 15A disposed on the charge accumulation layer is disposed, in the X direction, only on the active areas AA and split between the active areas AA, as shown in FIG. 4.

The intermediate insulating layer 15B includes, in the X direction, in the region between the active areas AA (over the air gap AG), a portion whose lower surface is exposed in the air gap AG and upwardly convex curved. In this embodiment, the highest point (i.e., the highest point in the Z-direction) of the lower surface of the intermediate insulating layer 15B is, in the X direction, generally centered between the active areas AA, and in the Z-direction, at generally the same position as the lower surface of the upper insulating layer 15C. Note that the highest point of the intermediate insulating layer 15B may not be centered between the active areas AA.

The upper insulating layer 15C is disposed, in the X direction, extending in the X direction over the memory cells MC, as shown in FIG. 4.

In addition, the insulating layers 15A to 15C are each, in the Y direction, formed only in the regions where the memory cells MC are formed. The insulating layers 15A to 15C are split between the memory cells MC.

The block insulating film 15 described herein has a three layer structure of the insulating films 15A to 15C, but it is not limited thereto. The block insulating film 15 may be, for example, a single material film or a stacked film of two layers. In addition, it may be a stacked film of four layers or more.

Then, between the active areas AA, the air gap AG is sandwiched between the upwardly convex curved lower surface of the intermediate insulating layer 15B and the surface of the semiconductor substrate 10. A portion or all of the air gap AG may be filled with, for example, a low permittivity material such as silicon oxide (SiO₂).

An electrically conductive layer 16 is deposited on the upper insulating layer 15C via a not-shown barrier metal. The electrically conductive layer 16 functions as the word-line WL. The electrically conductive layer 16 may include, for example, metal such as tungsten (W). The electrically conductive layer 16 has stacked thereon an interlayer insulating layer 17 of for example silicon oxide.

Note that an interface layer may be present between the insulating layer 13 and the metal layer 14 and between the block insulating film 15 and the metal layer 14.

### [Characteristics of Block Insulating Film 15]

Here, the characteristics of the block insulating film 15 in this embodiment will be described.

As described above, in this embodiment, the intermediate insulating film 15B included in the block insulating film 15 is formed in a shape whose lower surface has an upwardly convex curved portion in the region between the active areas AA. In other words, the intermediate insulating layer 15B in the active area AA has a reverse tapered shape with the X direction width increasing from the lower insulating layer 15A toward the upper insulating layer 15C. Such a shape may ensure a wide path where electric flux lines occur between the metal layer 14, which is the top layer of the charge accumulation layer, and the electrically conductive layer 16. It is because as shown in FIG. 4, a number of electric flux line paths may be ensured between the metal layer 14 and the electrically conductive layer 16 from the metal layer 14 to the electrically conductive layer 16, the electric flux line paths including electric flux line paths in the direction perpendicular to the substrate 10 (the direction of only the Z component) as well as electric flux line paths in directions oblique to the substrate 10 (the direction of the Z and X components) (the solid line in FIG. 4). In this way, the wide path of the electric flux lines is ensured between the metal layer 14 and the electrically conductive layer 16 so that sufficient capacitance may be ensured between the metal layer 14 and the electrically conductive layer 16.

In addition, the intermediate insulating layer 15B having an upwardly convex curved portion over the air gaps AG increases the area occupied by the air gaps AG between the memory cells MC adjacent in the X direction. The air gaps AG include an atmosphere having a relative permittivity generally the same as the vacuum permittivity, which is much lower than that of lanthanum aluminum silicate included in the intermediate insulating layer 15B. Therefore, this may more reliably reduce the electric flux lines (the dotted lines in FIG. 4) that occur between the metal layer 14 in one memory cell MC and the metal layer 14 in the adjacent memory cell MC via the lower insulating layer 15A and the overlying intermediate insulating layer 15B. The cell to cell interference may thus be reduced, suppressing the cell performance degradation.

Note that as described below, the intermediate insulating layer 15B is formed, using a hydrofluoric acid based solution such as a hydrogen fluoride solution, to have a lower surface in the upwardly convex curve. The hydrofluoric acid based solution dose not act on the materials such as hafnium oxide included in the lower and upper insulating layers 15A and 15C so that the shapes of the lower and upper insulating layers 15A and 15C remain almost unchanged.

### [Method of Manufacturing Non-Volatile Semiconductor Memory Device According to First Embodiment]

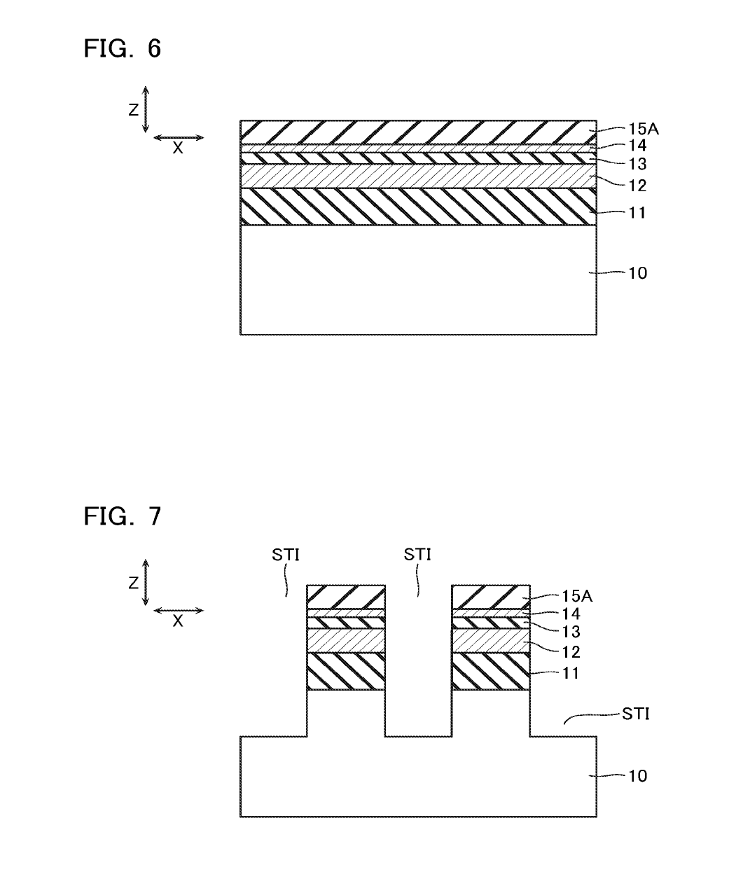

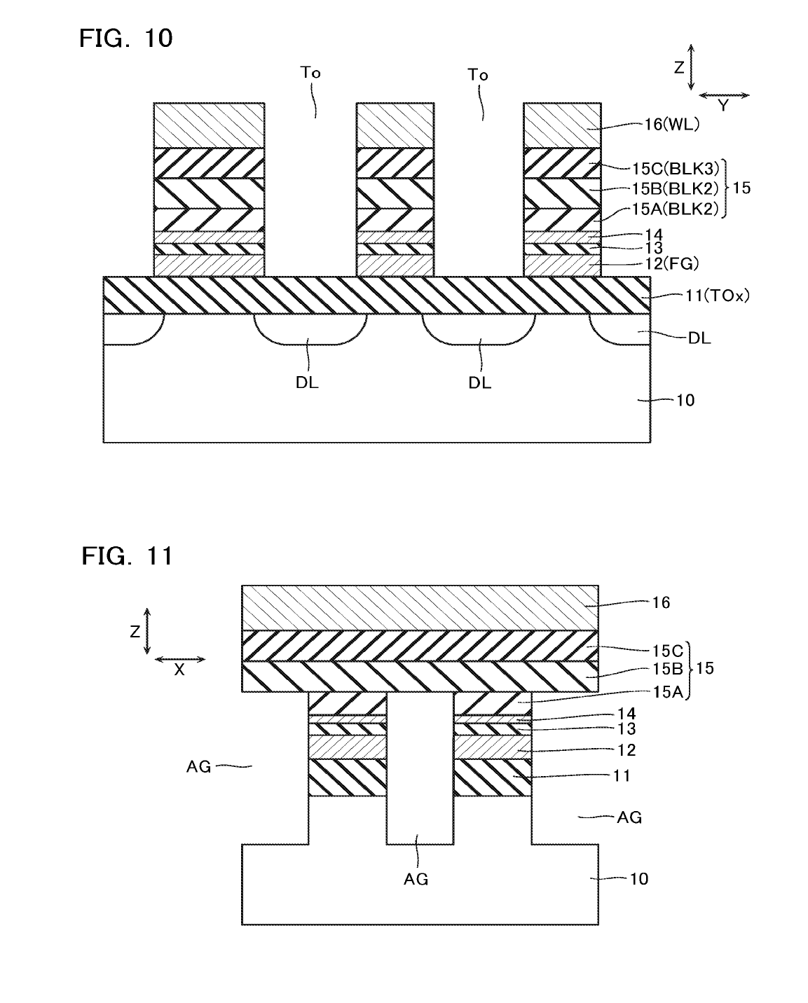

Next, with reference to FIG. 6 to FIG. 11, a method of manufacturing the non-volatile semiconductor memory device according to this embodiment will be described. FIG. 6 to FIG. 9 and FIG. 11 each show an X direction cross-section in FIG. 3, which corresponds to FIG. 4. FIG. 10 shows a Y direction cross-section in FIG. 3, which corresponds to FIG. 5.

First, as shown in FIG. 6, the semiconductor substrate is deposited with materials by CVD or the like. The materials are for, sequentially from the semiconductor substrate 10 side, the gate-insulating film 11 (the tunnel insulating film), the floating gate electrode 12, the insulating film 13, the metal layer 14, and the lower insulating film 15A (the materials being, for example, silicon oxide, polysilicon, silicon nitride, ruthenium, and hafnium oxide, respectively).

Then, as shown in FIG. 7, isolation trenches STI extending in the Y direction as the longitudinal direction are formed in the X direction at a predetermined interval. The isolation trenches STI pass through the above stack of materials and dig a portion of the semiconductor substrate 10.

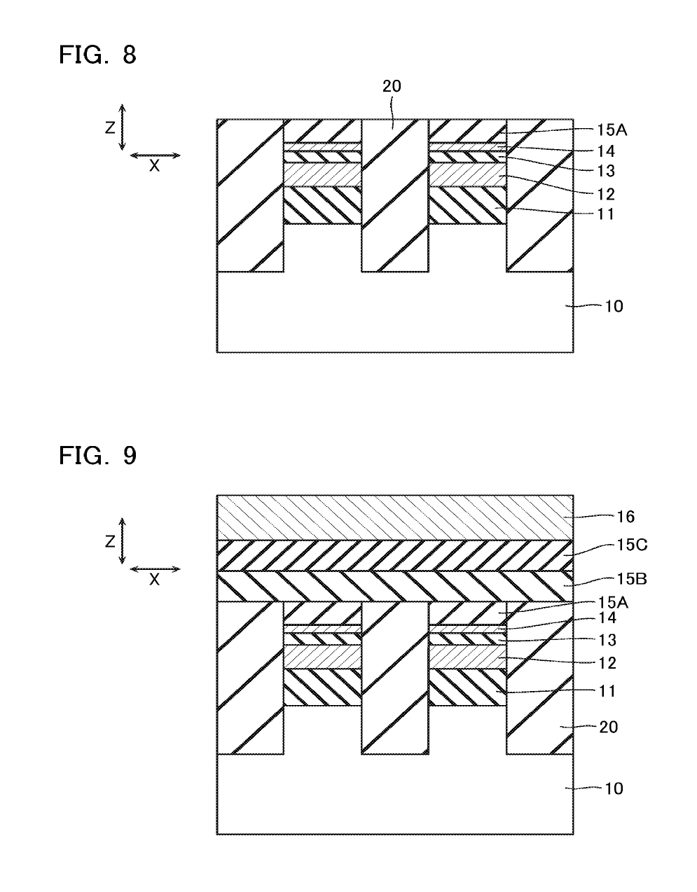

As shown in FIG. 8, each isolation trench STI is filled with an embedding film 20. Preferably, the embedding film 20 includes a material that has a higher etching rate than the intermediate insulating layer 15B in the chemical solution used to form the lower surface of the intermediate insulating layer 15B into the upwardly convex curve by wet etching. For the intermediate insulating layer 15B of lanthanum aluminum silicate and the wet etching chemical solution of a hydrofluoric acid based solution, polysilazane may be used, for example. Then, depending on the composition ratio of lanthanum aluminum silicate, the etching rate in the hydrofluoric acid needs to be adjusted. After filling the isolation trenches STI with the embedding film 20, the upper surface is planarized by CMP or the like to be generally flush with the upper surface of the lower insulating layer 15A.

As shown in FIG. 9, the entire surface of the stack and the embedding film 20 on the semiconductor substrate 10 is covered by depositing materials for the intermediate insulating layer 15B, the upper insulating layer 15C, and the electrically conductive layer 16 (for example, lanthanum aluminum silicate (LaAlSiO), hafnium oxide, and tungsten, respectively) by CVD or the like.

As shown in FIG. 10, etching is performed through the stack from the floating gate electrode 12 to the electrically conductive layer 16 to form trenches To that extend in the X direction and are disposed in the Y direction at a predetermined interval. Then, in the regions of the substrate 10 where the trenches To are formed, with a mask such as the above stack, ion implantation of n-type impurities (phosphorus (P) or the like) is performed in self-alignment, then thermal treatment of 955° C., 30 second is performed to diffuse the impurities to form diffusion layers DL. Each diffusion layer DL connects in series the memory cells MC arranged in the Y direction to form the memory string.

Then, as shown in FIG. 11, wet etching is performed using a hydrofluoric acid based solution such as a dilute hydrofluoric acid solution to remove the embedding films 20. As described above, the etching rate of the embedding film 20 in the hydrofluoric acid based solution is higher than the etching rate of the intermediate insulating layer 15B in the hydrofluoric acid based solution. Also, materials such as polysilicon in the floating gate electrode 12, thermally-oxidized film in the insulating layer 11, silicon nitride in the insulating layer 13, and hafnium oxide in the lower insulating layer 15A each have a lower etching rate in the hydrofluoric acid based solution. Therefore, as shown in FIG. 11, after the wet etching is started, the embedding film 20 is first removed as time passes.

Then, continuing the wet etching after removing the embedding film 20 removes the intermediate insulating layer 15B from around the center of its lower surface, thus forming the upwardly convex curve. Note that if the intermediate insulating layer 15B includes material such as lanthanum aluminum silicate, too high percentage of lanthanum may increase the etching rate in the hydrofluoric acid based solution, thus removing the embedding film 20 as well as removing the entire intermediate insulating layer 15B over the active area AA. To prevent such a situation, the percentage of lanthanum is such that the etching rate of the intermediate insulating layer 15B in the hydrofluoric acid based solution is sufficiently lower than the etching rate of the embedding film 20 in the hydrofluoric acid based solution. Additionally, the etching condition is adjusted so that the entire embedding film 20 is removed and only the lower surface central portion of the intermediate insulating layer 15B is removed, thus providing the upwardly convex curve.

Finally, the upper layer of the upper insulating layer 15C is deposited with the interlayer insulating layer 17 including for example silicon oxide or the like, thus providing the configuration shown in FIG. 4 and FIG. 5.

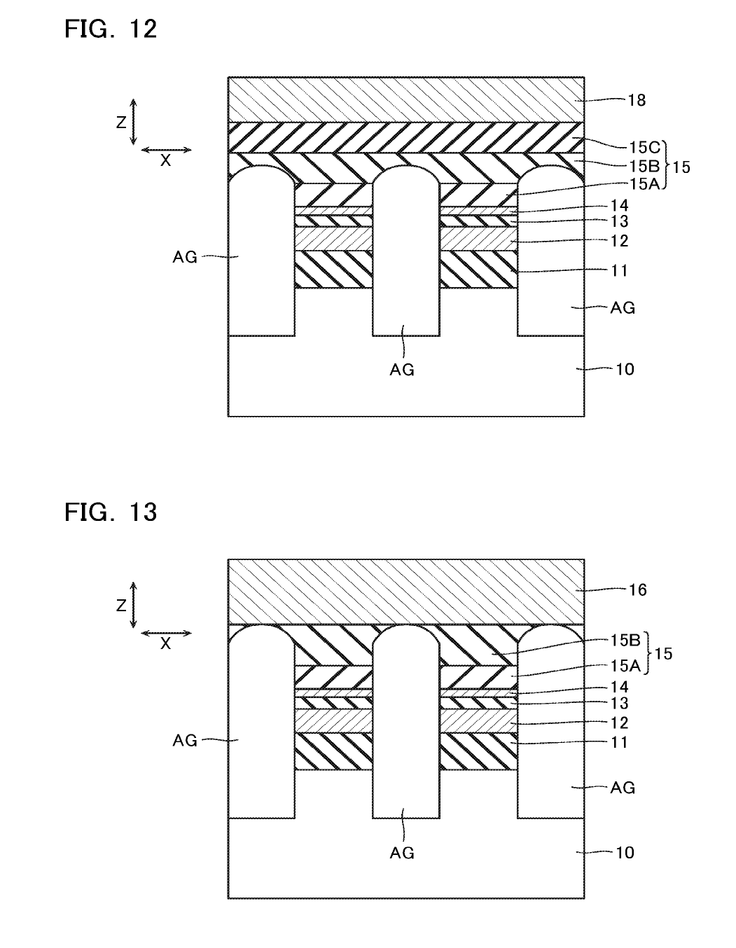

Note that although the foregoing describes the air gaps AG extending in the Y direction and the trenches To extending in the X direction being filled with atmosphere, they may alternatively be filled with for example a low permittivity material such as silicon oxide. In this case, after removing the embedding film 20 and a portion of the lower surface of the intermediate insulating layer 15B by wet etching as shown in FIG. 12, deposition is performed by for example an anisotropic deposition process such as plasma CVD.

### Non-Volatile Semiconductor Memory Device According to Second Embodiment

Next, a non-volatile semiconductor memory device according to a second embodiment will be described with reference to FIG. 12.

The non-volatile semiconductor memory device according to the second embodiment has generally the same entire configuration as the non-volatile semiconductor memory device according to the first embodiment. Like elements are provided with like reference numerals and their description is omitted here. The same holds true for third and subsequent embodiments.

### [Configuration]

The non-volatile semiconductor memory device according to the second embodiment is different from the non-volatile semiconductor memory device according to the first embodiment in that the intermediate insulating layer 15B in the block insulating layer 15 has a partially different configuration.

As shown in FIG. 12, in the non-volatile semiconductor memory device according to the second embodiment, the intermediate insulating layer 15B has an exposed lower surface and an upwardly convex curved portion like the first embodiment. More specifically, the intermediate insulating layer 15B has an exposed lower surface and is upwardly convex curved between the active areas AA (between the channel regions). However, in the second embodiment, the lower surface of the intermediate insulating layer 15B has a highest point whose X direction position is generally centered in the active area AA (the channel region) as in the first embodiment and Z-direction height is around a midpoint between the upper surface of the lower insulating layer 15A and the lower surface of the upper insulating layer 15C. In other words, the Z-direction height of the highest point of the lower surface of the intermediate insulating layer 15B is not the same as the height of the lower surface of the upper insulating layer 15C. Such a configuration may also provide effects similar to those of the non-volatile semiconductor memory device according to the first embodiment.

### [Manufacturing Method]

The non-volatile semiconductor memory device according to the second embodiment is manufactured in the same way as the method of manufacturing the non-volatile semiconductor memory device according to the first embodiment until the processes shown in FIG. 6 to FIG. 11. Specifically, after the trenches To are formed as shown in FIG. 10, the hydrofluoric acid based solution is used to perform the wet etching. Then, like the first embodiment, the embedding film 20 of polysilazane is first removed as shown in FIG. 11.

Then, in the second embodiment, as shown in FIG. 12, the etching condition is adjusted so that the lower surface of the intermediate insulating layer 15B has an upwardly convex curved portion and has a highest point whose Z-direction position is around a midpoint between the upper surface of the lower insulating layer 15A and the upper insulating layer 15C.

### Third Embodiment

Next, a non-volatile semiconductor memory device according to a third embodiment will be described with reference to FIG. 13.

In the non-volatile semiconductor memory device according to the third embodiment, the block insulating film has a configuration different from that in the first embodiment.

As shown in FIG. 13, in the non-volatile semiconductor memory device according to the third embodiment, the block insulating film 15 has a two layer structure of the lower insulating layer 15A and the intermediate insulating layer 15B. Specifically, it is the same as the configuration of the non-volatile semiconductor memory device according to the first embodiment minus the upper insulating layer 15C. Then, the intermediate insulating layer 15B has a lower surface exposed and upwardly convex curved between the active areas AA, and an upper surface in contact with the lower surface of the electrically conductive layer 16.

The configuration in the third embodiment may also provide effects similar to those in the first and second embodiments.

### Fourth Embodiment

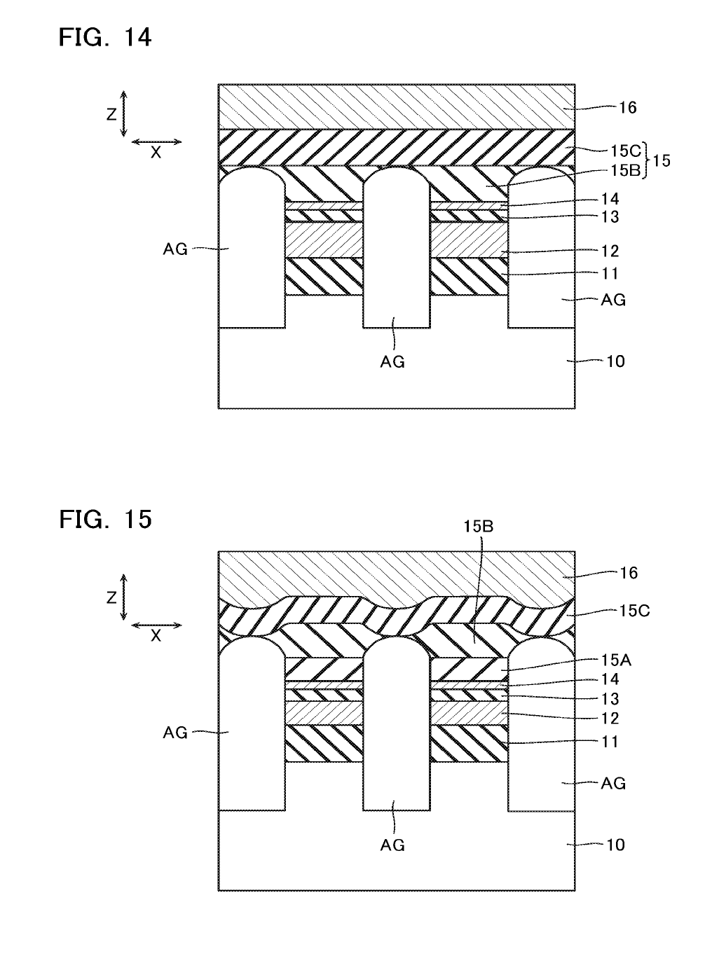

Next, a non-volatile semiconductor memory device according to a fourth embodiment will be described with reference to FIG. 14.

In the non-volatile semiconductor memory device according to the fourth embodiment, the block insulating film has a configuration different from that in the first embodiment.

As shown in FIG. 14, in the non-volatile semiconductor memory device according to the fourth embodiment, the block insulating film 15 has a two layer structure of the intermediate insulating layer 15B and the upper insulating layer 15C. Specifically, it is the same as the non-volatile semiconductor memory device according to the first embodiment minus the lower insulating layer 15A. Then, the intermediate insulating layer 15B has a lower surface exposed and upwardly convex curved between the active areas AA. In addition, in the active area AA, the lower surface of the intermediate insulating layer 15B is in contact with the upper surface of the electrically conductive layer 14.

The configuration in the fourth embodiment may also provide effects similar to those in the first and second embodiments.

### Fifth Embodiment

Next, a non-volatile semiconductor memory device according to a fifth embodiment will be described with reference to FIG. 15 to FIG. 17.

### [Configuration]

In the above non-volatile semiconductor memory device according to the fifth embodiment, the block insulating film 15 has a layer configuration similar to that in the first embodiment.

In the non-volatile semiconductor memory device according to the fifth embodiment, as shown in FIG. 15, the intermediate insulating layer 15B has a lower surface exposed and upwardly convex curved between the active areas AA, like the above embodiments. Then, this embodiment is different from the above embodiments in that, between the active areas AA, the upper surface of the intermediate insulating layer 15B, the upper and lower surfaces of the upper insulating layer 15C, and the lower surface of the electrically conductive layer 16 are downwardly convex in the Z-direction. Specifically, the upper surface of the intermediate insulating layer 15B, the upper and lower surfaces of the upper insulating layer 15C, and the lower surface of the electrically conductive layer 16 are formed in a curve so that they decrease the Z-direction height in the region from the active area AA to between the active areas AA. As described above, in this embodiment, the lower insulating layer 15A, the intermediate insulating layer 15B, and the upper insulating layer 15C have an upper surface height in the region between the active areas AA (over the air gaps AG) (the upper surface position of the upper insulating layer 15C in the Z-direction) lower than the upper surface height in the region of the active area AA (the upper surface position of the upper insulating layer 15C in the Z-direction in the active area AA). The curve shape may not be upwardly convex unlike the shape of the lower surface of the intermediate insulating layer 15B in the above embodiments.

In the non-volatile semiconductor memory device according to the fifth embodiment, in the region between the active areas AA, the lower surface of the electrically conductive layer 16 has a Z-direction height lower than those in the above first to fourth embodiments. This reduces the distance between the metal layer 14 in each memory cell MC and the lower surface of the electrically conductive layer 16 between the active areas AA. The electrically conductive layer 16 functions as the word-lines WL. This increases the density of the electric flux lines generated between the metal layer 14 and the electrically conductive layer 16, thus increasing the capacitances of the memory cells MC.

### [Manufacturing Method]

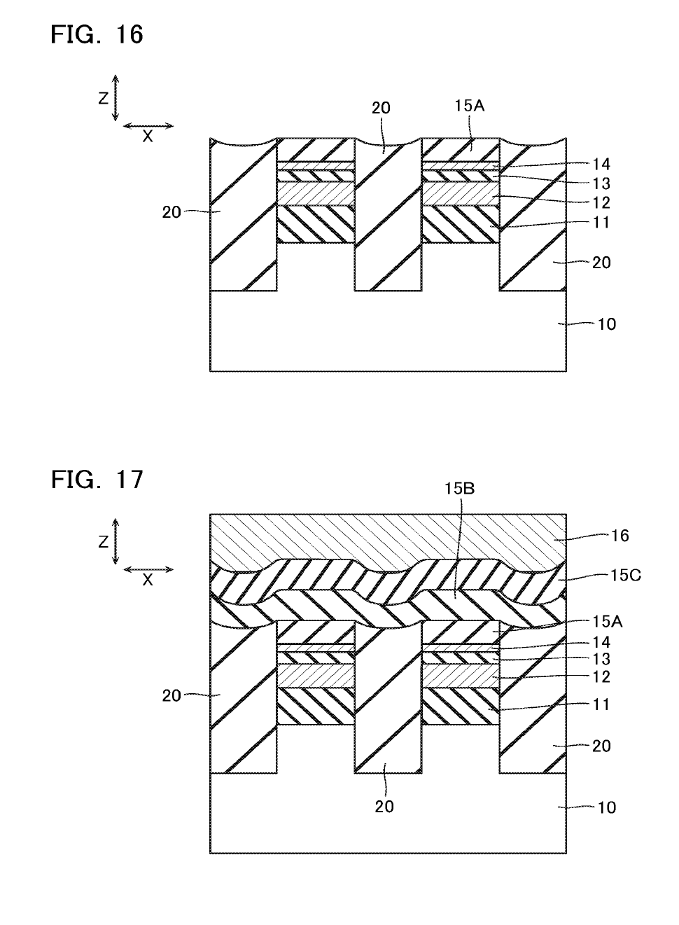

A method of manufacturing the non-volatile semiconductor memory device according to the fifth embodiment will be described with reference to FIG. 16 and FIG. 17.

The non-volatile semiconductor memory device according to the fifth embodiment is manufactured in a way similar to the method in the first embodiment until the processes shown in FIG. 6 to FIG. 8.

After filling and planarizing the embedding film 20 as shown in FIG. 8, the upper surface of the lower insulating layer 15A is masked, for example, and the surface of the embedding film 20 is etched to retract the surface (etch back) as shown in FIG. 16. In this way, between the active areas

AA, the upper surface of the embedding film 20 has a downward curved shape.

As shown in FIG. 17, the intermediate insulating layer 15B, the upper insulating layer 15C, and the electrically conductive layer 16 are deposited. In this way, these layers are deposited, between the active areas AA, in a curve along the curved shape of the surface of the embedding film 20.

Like the process in the first embodiment shown in FIG. 10, a plurality of trenches To extending in the X direction are formed and the diffusion layers DL are formed.

Then, like the process in the first embodiment shown in FIG. 11, wet etching is performed to remove the embedding film 20 and fabricate the intermediate insulating layer 15B. Also in this embodiment, like the above described embodiments, the etching condition is adjusted so that the lower surface of the intermediate insulating layer 15B is upwardly convex curved between the active areas AA.

The above processes provide the configuration shown in FIG. 15.

### Sixth Embodiment

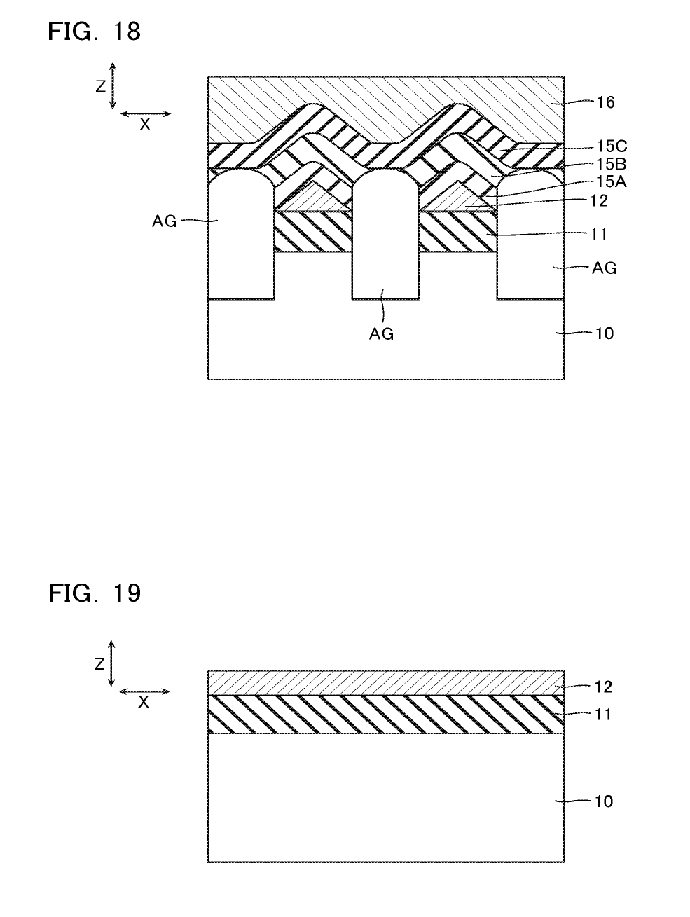

Next, a non-volatile semiconductor memory device according to a sixth embodiment will be described with reference to FIG. 18 to FIG. 25.

### [Configuration]

In the non-volatile semiconductor memory device according to the sixth embodiment, the layers disposed over the insulating layer 13 have different shapes from those in the first embodiment. In addition, the sixth embodiment does not include the insulating layer 13 or the metal layer 14, which are disposed in the first embodiment.

In the non-volatile semiconductor memory device according to the sixth embodiment, as shown in FIG. 18, the floating gate electrode 12 as the charge accumulation layer disposed on the insulating layer 11 has a generally triangle shape. In other words, the floating gate electrode 12 has a tapered shape with the X direction width decreasing upward in the Z-direction.

In addition, for the lower insulating layer 15A, the intermediate insulating layer 15B, the upper insulating layer 15C, and the electrically conductive layer 16 that are disposed over the floating gate electrode 12, their lower surfaces have an upward projecting shape along the shape of the electrically conductive layer 14 in the active area AA.

The configuration of the non-volatile semiconductor memory device according to the sixth embodiment may also provide effects similar to those described above.

### [Manufacturing Method]

A method of manufacturing the non-volatile semiconductor memory device according to the sixth embodiment will be described with reference to FIG. 19 to FIG. 25.

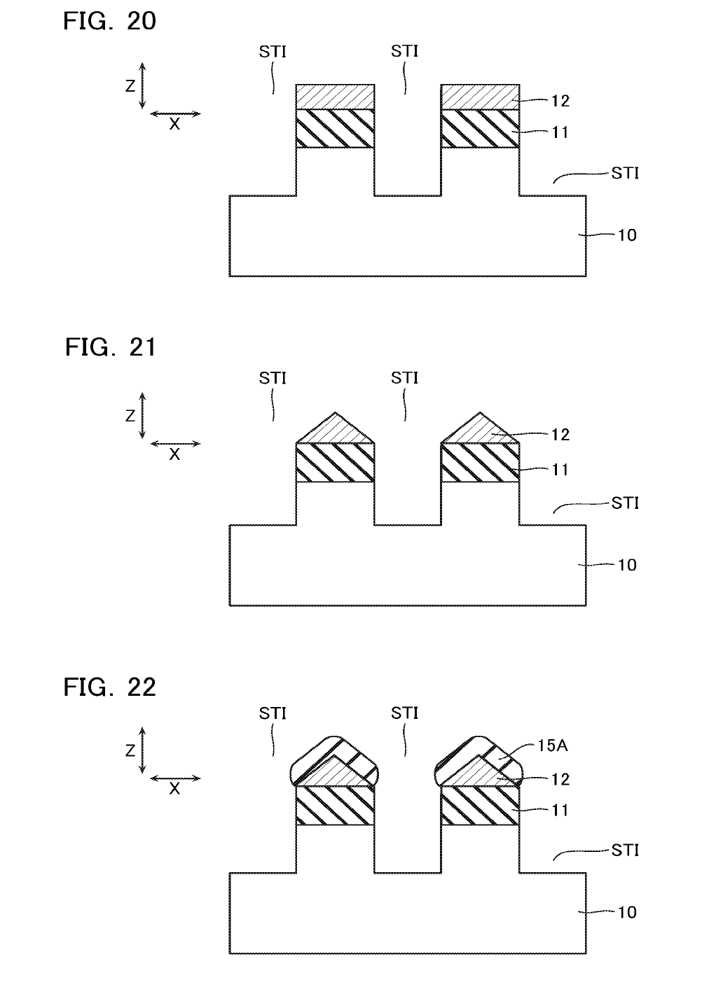

As shown in FIG. 19, the semiconductor substrate 10 of silicon or the like is deposited with the gate-insulating film 11 of silicon oxide or the like and the floating gate electrode 12 of polysilicon or the like sequentially by CVD or the like. As shown in FIG. 20, isolation trenches STI extending in the Y direction as the longitudinal direction are formed in the X direction at a predetermined interval. The isolation trenches STI pass through the above stack of materials and dig a portion of the semiconductor substrate 10.

Forming STI is combined with trimming and fabricating the upper surface of the floating gate electrode 12 so that the X direction width of the floating gate electrode 12 decreases upward in the Z-direction, as shown in FIG. 21.

As shown in FIG. 22, the lower insulating layer 15A of for example hafnium oxide or the like is deposited. During this deposition, because of the floating gate electrode 12 having a tapered shape with the width decreasing upward, the lower insulating layer 15A is formed into a shape projecting beyond the X direction width of the structure having the floating gate electrode 12 and the underlying layers, as shown in FIG. 22. The deposition may use a deposition process with a relatively low coverage.

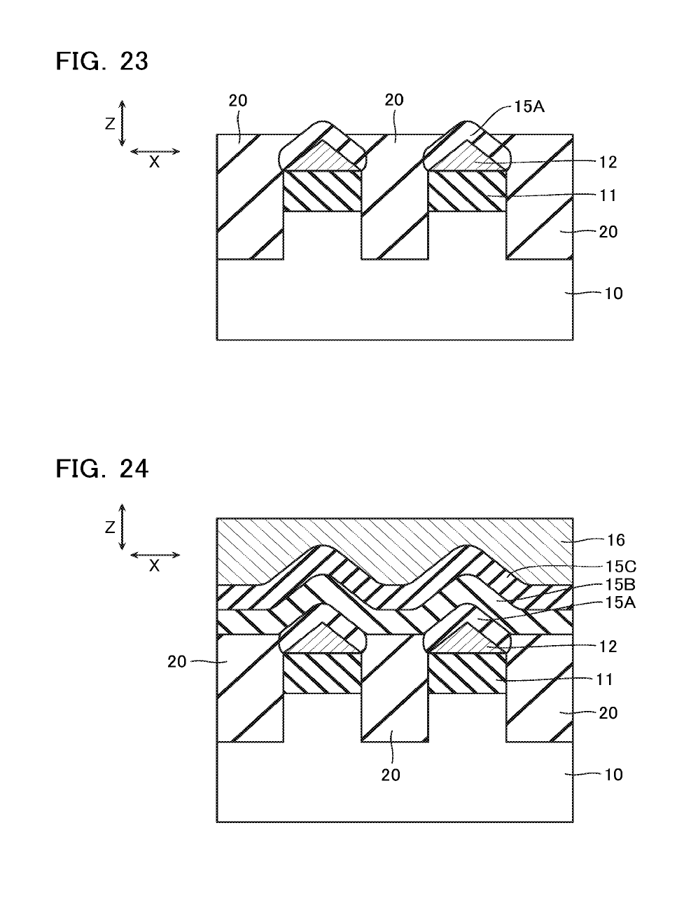

As shown in FIG. 23, each isolation trench STI is deposited with the embedding film 20 of polysilazane.

As shown in FIG. 24, the intermediate insulating layer 15B, the upper insulating layer 15C, and the electrically conductive layer 16 are sequentially stacked.

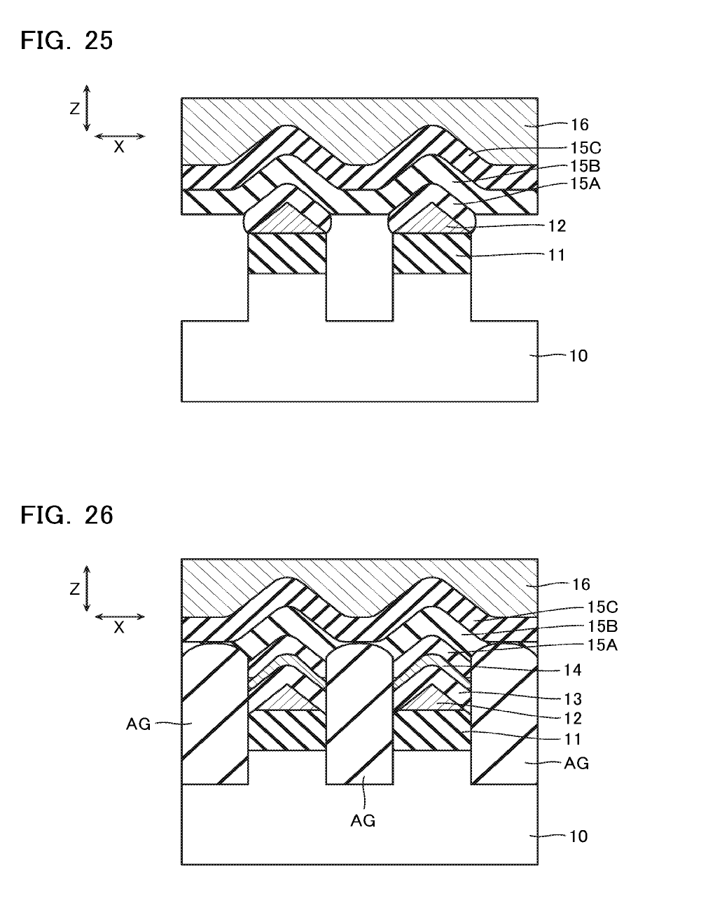

As shown in FIG. 25, like the processes in the first embodiment shown in FIG. 10, trenches extending in the X direction are formed and then wet etching is performed to remove first the embedding film 20.

Then, like the above embodiments, etching is performed until the lower surface of the intermediate insulating layer 15B has an upwardly convex curve between the active areas AA, thus providing the configuration shown in FIG. 18.

### Seventh Embodiment

A non-volatile semiconductor memory device according to a seventh embodiment will be described with reference to FIGS. 26 to 29.

### [Configuration]

The non-volatile semiconductor memory device according to the seventh embodiment further includes, in addition to the components in the sixth embodiment, the insulating layer 13 and the metal layer 14 as the charge accumulation layer as shown in FIG. 26.

Specifically, the non-volatile semiconductor memory device according to the seventh embodiment has a tapered shape with the X direction width of the floating gate electrode 12 decreasing upward in the Z-direction.

In addition, for the insulating layer 13, the metal layer 14, the lower insulating layer 15A, the intermediate insulating layer 15B, the upper insulating layer 15C, and the electrically conductive layer 16 that are disposed over the floating gate electrode 12, their lower surfaces have an upward projecting shape along the shape of the floating gate electrode 12 in the active area AA.

The configuration of the non-volatile semiconductor memory device according to the seventh embodiment may also provide effects similar to those described above.

### [Manufacturing Method]

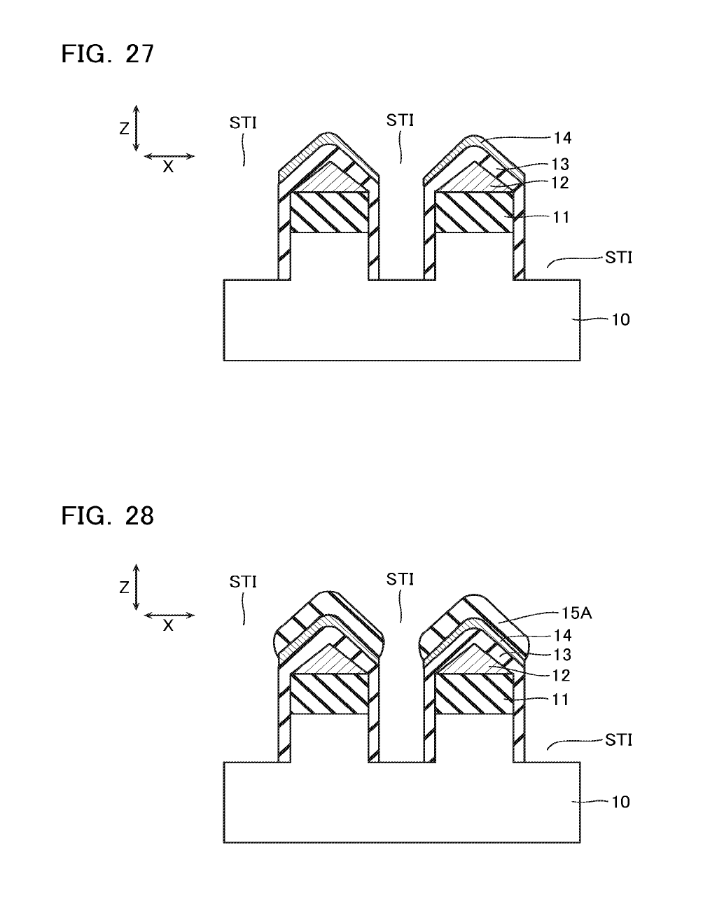

A method of manufacturing the non-volatile semiconductor memory device according to the seventh embodiment will be described with reference to FIG. 27 to FIG. 29. Note that as described above, the seventh embodiment has a similar configuration to the sixth embodiment and thus only different portions from those in the sixth embodiment will be described.

The manufacturing method in this embodiment is similar to that in the sixth embodiment until the processes of depositing, trimming and fabricating the floating gate electrode 12 as described in FIG. 19 to FIG. 21.

As shown in FIG. 27, the insulating layer 13 of silicon nitride or the like and the metal layer 14 of ruthenium (Ru) or the like are sequentially stacked.

The insulating layer 13 may be deposited by, for example, low pressure CVD (LPCVD). Deposition of silicon nitride by LPCVD deposits the insulating layer 13 also on the side surface of the structure in the active area AA, as shown in FIG. 27.

The deposited insulating layer 13 has a thickness of, for example, about 1 nm.

Meanwhile, the metal layer 14 may be deposited by a sputtering method. Sputtering deposits the metal layer 14 on the upper surface of the insulating layer 13 with little deposition on the side surface, as shown in FIG. 27. The deposited metal layer 14 has a thickness of, for example, about 0.1 nm.

As shown in FIG. 28, the upper surface of the metal layer 14 is deposited with the lower insulating layer 15A of, for example, hafnium oxide or the like. This process is similar to the process shown in FIG. 22. Specifically, the lower insulating layer 15A of material such as hafnium oxide is deposited using a deposition process having a relatively low coverage. The lower insulating layer 15A is formed into a shape with the X direction width projecting beyond the X direction width of the structure of the metal layer 14 and the underlying layers.

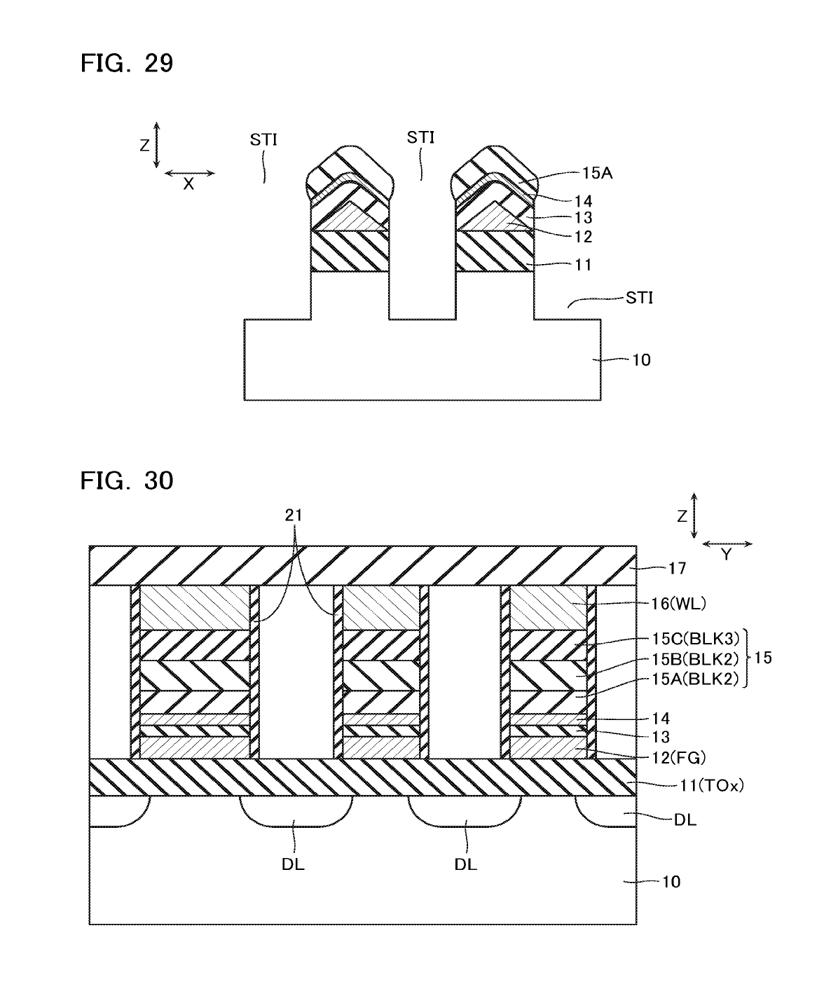

As shown in FIG. 29, in order to remove the insulating layer 15 deposited on the side surface of the structure in the active area AA, processing such as using a hot phosphorus acid solution is performed. Note that before this processing, processing such as using hydrochloric acid (HCl) may be performed to remove a small amount of metal layer 14 attached during the deposition of the metal layer 14.

Then, like the processes described in the sixth embodiment in FIG. 23 to FIG. 25, the embedding film 20 is deposited, the intermediate insulating layer 15B, the upper insulating layer 15C, and the electrically conductive layer 16 are deposited, the embedding film 20 is removed, and the intermediate insulating layer 15A is fabricated or the like to provide the configuration shown in FIG. 26.

### Eighth Embodiment

Next, a non-volatile semiconductor memory device according to an eighth embodiment will be described with reference to FIG. 30.

### [Configuration]

The non-volatile semiconductor memory device according to the eighth embodiment is similar to that in first embodiment with respect to the stacked structure of each memory cell MC and the shapes of the layers including the lower surface of the intermediate insulating layer 15B.

The non-volatile semiconductor memory device according to the eighth embodiment is different from that in the first embodiment in that as shown in FIG. 30, the Y direction side walls of the memory cells MC and the select transistor SG1 are provided with a protective film 21. Note that although not shown in FIG. 30, the source-side select transistor SG2 is also provided with, on its Y direction side walls, the protective film 21.

The protective film 21 act as protecting, during the wet etching in the fabricating of the embedding film 20 and the lower surface of the intermediate insulating layer 15B, the layers included in the memory cells MC and the select transistors SG1 and SG2 from being etched and retracted. Because the wet etching uses the hydrofluoric acid based solution as described above, the protective film 21 preferably includes, for example, a material such as silicon nitride having a low etching rate in the hydrofluoric acid based solution.

### [Manufacturing Method]

The non-volatile semiconductor memory device according to the eighth embodiment is manufactured in a way similar to the method in the first embodiment until the processes shown in FIG. 6 to FIG. 10.

After forming the trenches To and the diffusion layers DL as described in FIG. 10, the CVD process and Reactive ion etching (RIE) or the like are used to deposit the side wall protective film 21 to cover the entire side surfaces in the Y direction of the memory cells MC and the select transistor SG1. The side wall protective film 21 functions as a protective layer against wet etching of the Y direction side surface.

Then, like the process described in the first embodiment in FIG. 11, wet etching is performed to remove the embedding film 20 and fabricate the lower surface of the intermediate insulating layer 15B into an upwardly convex curve.

### Ninth Embodiment

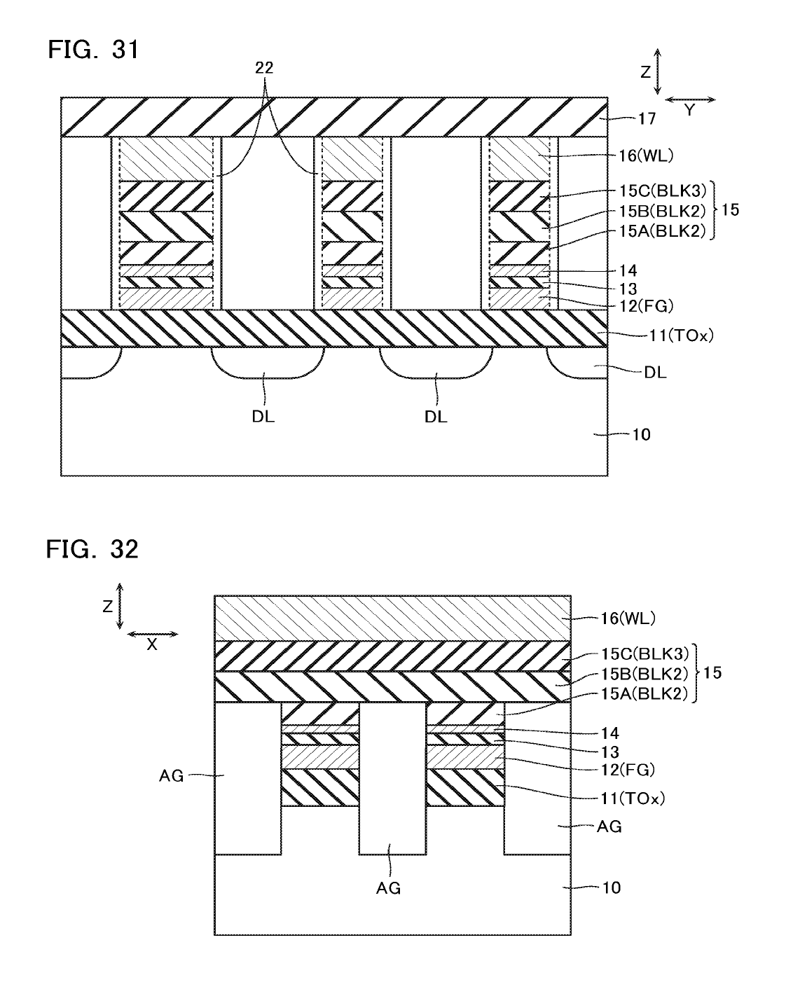

A non-volatile semiconductor memory device according to a ninth embodiment will be described with reference to FIG. 31.

The non-volatile semiconductor memory device according to the ninth embodiment is similar to that in the first embodiment, as in the eighth embodiment, with respect to the stacked structure of each memory cell MC and the shapes of the layers including the lower surface of the intermediate insulating layer 15B.

In the non-volatile semiconductor memory device according to the ninth embodiment, as shown in FIG. 31, the Y direction side walls of the memory cells MC and the select transistor SG1 may be injected with an additive 22 such as aluminum and nitrogen. The additive 22 is injected after forming the trenches To as described in FIG. 10 like the deposition of the protective film 21 as described in FIG. 30. The injection method of the additive 22 may be selected as appropriate from chemical processes such as CVD and physical processes such as sputtering depending on the additive types or the like.

The configuration of the non-volatile semiconductor memory device according to the ninth embodiment may also provide effects similar to those in the eighth embodiment. Specifically, in this embodiment, the regions near the Y direction side walls of the memory cells MC and the select transistors SG1 and SG2 function as the protective layer against the wet etching, the regions having the additive 22 added therein.

Note that although the above eighth and ninth embodiments have been described with respect to a layer configuration and a shape of the intermediate insulating layer 15B similar to those in the first embodiment, the present invention is not limited thereto. Specifically, the eighth and ninth embodiments may be combined with any of the first to seventh embodiments.

### Comparative Example

Finally, the non-volatile semiconductor memory device according to the comparative example will be described with reference to FIG. 32.

The non-volatile semiconductor memory device according to the comparative example shown in FIG. 32 has generally the same entire configuration as that in the first embodiment.

However, in the non-volatile semiconductor memory device according to the comparative example, the intermediate insulating layer 15B has a different material and shape from that in the first embodiment.

The intermediate insulating layer 15B of the non-volatile semiconductor memory device according to the comparative example is formed of silicon oxide. In addition, the intermediate insulating layer 15D has a shape formed in a flat plate and does not have the upwardly convex curved portion.

In the non-volatile semiconductor memory device according to the comparative example, the intermediate insulating layer 15B of silicon oxide has a lower permittivity, thus making it hard to ensure sufficient capacitance.

Additionally, a thinner intermediate insulating layer 15B to bring closer the metal layer 14 and the electrically conductive layer 16 for higher capacitance causes a problem that provides insufficient insulating property, generating leak current.

### OTHERS

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a plurality of channel layers;
a gate-insulating film disposed on the channel layers;
a floating gate electrode disposed on the gate-insulating film;
a block insulating film disposed over the floating gate electrode, the block insulating film comprising at least a first insulating film and a second insulating film, the second insulating film comprising lanthanum and aluminum; and
a control gate electrode disposed on the block insulating film,
the second insulating film comprising an upwardly convex curved portion in a region between the channel layers.

2. The non-volatile semiconductor memory device according to claim 1, wherein
the upwardly convex curved second insulating film has a lower surface, the lower surface having a highest point generally centered between the channel layers disposed adjacent.

3. The non-volatile semiconductor memory device according to claim 1, wherein
a protective layer is provided on side surfaces of the floating gate electrode, the block insulating film, and the control electrode, the side surfaces being in a channel layer extension direction.

4. The non-volatile semiconductor memory device according to claim 1, wherein
the block insulating film has an upper surface, the upper surface in the region between the channel layers having a lower height than the upper surface in regions over the channel layers.

5. The non-volatile semiconductor memory device according to claim 1, wherein
the block insulating film has a stacked structure, the stacked structure comprising a third insulating film, the third insulating film being disposed over the channel layers and split between the channel layers, the second insulating film disposed on the third insulating film, and the first insulating film disposed on the second insulating film.

6. The non-volatile semiconductor memory device according to claim 1, wherein
a charge accumulation layer is provided between the floating gate electrode and the block insulating film, the charge accumulation layer having a tapered shape with a width decreasing upward.

7. The non-volatile semiconductor memory device according to claim 1, wherein
the second insulating film has an air gap below it in the region between the channel layers.

8. A non-volatile semiconductor memory device, comprising
a plurality of channel layers;
a gate-insulating film disposed on the channel layers;
a floating gate electrode disposed on the gate-insulating film;
a block insulating film disposed over the floating gate electrode, the block insulating film comprising at least a first insulating film and a second insulating film, the second insulating film comprising aluminum; and
a control gate electrode disposed on the block insulating film,
the second insulating film comprising an upwardly convex curved portion in a region between the channel layers.

9. The non-volatile semiconductor memory device according to claim 8, wherein
the upwardly convex curved second insulating film has a highest point generally centered between the adjacent channel layers.

10. The non-volatile semiconductor memory device according to claim 8, wherein
a protective layer is provided on side surfaces of the floating gate electrode, the block insulating film, and the control electrode, the side surfaces being in a channel layer extension direction.

11. The non-volatile semiconductor memory device according to claim 8, wherein
the upper surface of the block insulating film in the region between the channel layers has a lower height than the upper surface in a region over the floating gate electrode.

12. The non-volatile semiconductor memory device according to claim 8, wherein
the block insulating film has a stacked structure, the stacked structure comprising a third insulating film split between the channel layers, the second insulating film disposed on the third insulating film, and the first insulating film disposed on the second insulating film.

13. The non-volatile semiconductor memory device according to claim 8, wherein
a charge accumulation layer is provided between the floating gate electrode and the block insulating film, the charge accumulation layer having a tapered shape with a width decreasing upward.

14. The non-volatile semiconductor memory device according to claim 8, wherein
the second insulating film has an air gap below it in the region between the channel layers.

15. A method of manufacturing a non-volatile semiconductor memory device, the non-volatile semiconductor memory device comprising a plurality of channel layers, a gate-insulating film disposed on the channel layers, a floating gate electrode disposed on the gate-insulating film, a block insulating film disposed over the floating gate electrode, the block insulating film comprising at least a first insulating film and a second insulating film, the second insulating film comprising aluminum, and a control gate electrode disposed on the block insulating film,
the method comprising:
forming the gate-insulating film on the channel layers;
forming the floating gate electrode on the gate-insulating film;
forming an isolation trench dividing the channel layers;
filling an embedding film in the isolation trench;
forming the block insulating film on the floating gate electrode so that the lower surface of the second insulating film is in contact with the upper surface of the embedding film in the channel layers;
forming the control gate electrode on the block insulating film; and
wet etching the embedding film and the second insulating film to remove the embedding film to form an air gap and remove a portion of the second insulating film.

16. The method of manufacturing a non-volatile semiconductor memory device according to claim 15, wherein
a portion of the second insulating film is removed so that the lower surface of the second insulating film is formed in an upwardly convex curve.

17. The method of manufacturing a non-volatile semiconductor memory device according to claim 16, wherein
the lower surface of the second insulating film is formed so that the highest point of the upwardly convex curve is generally centered between the channel layers.

18. The method of manufacturing a non-volatile semiconductor memory device according to claim 15, wherein
before the wet etching, a plurality of second isolation trenches are formed in a direction perpendicular to the isolation trench, and
a protective layer is formed on side surfaces of the floating gate electrode, the block insulating film, and the control electrode, the side surfaces being exposed by forming the second isolation trenches.

19. The method of manufacturing a non-volatile semiconductor memory device according to claim 15, wherein
the block insulating film is formed so that the upper surface of the block insulating film in a region between the channel layers has a lower height than the upper surface in a region over the channel layers.

20. The method of manufacturing a non-volatile semiconductor memory device according to claim 15, wherein
a charge accumulation layer is formed between the floating gate electrode and the block insulating film, the charge accumulation layer having a tapered shape with a width decreasing upward.
